(19) United States
(12) Patent Application Publication
(10) Pub. No.: US 2023/0170417 A1
(43) Pub. Date: Jun. 1, 2023

(54) HIGH VOLTAGE SEMICONDUCTOR DEVICE AND METHOD OF MANUFACTURING SAME

(71) Applicant: DB HiTek Co., Ltd., Bucheon-si (KR)

(72) Inventor: Ji Ye PARK, Bucheon-si (KR)

(21) Appl. No.: 18/054,973

(22) Filed: Nov. 14, 2022

(30) Foreign Application Priority Data
Dec. 1, 2021 (KR) 10-2021-0169861

(51) Int. Cl. H01L 29/78; H01L 29/06; H01L 29/10; H01L 29/40; H01L 29/45; H01L 21/285; H01L 21/265; H01L 21/266; H01L 29/66

(52) U.S. Cl. CPC H01L 29/7835; H01L 29/0623; H01L 29/1095; H01L 29/402; H01L 29/45; H01L 29/7823; H01L 21/28518; H01L 21/26513; H01L 21/266; H01L 29/66492; H01L 29/66681

(57) ABSTRACT

Disclosed are a high voltage semiconductor device and a method of manufacturing the high voltage semiconductor device. More specifically, a high voltage semiconductor device and a method of manufacturing the high voltage semiconductor device omit a conventional deep NDT region in a body region of the device, and include a HV-NLDD region to minimize the width of the body region, thereby improving integration and on-resistance of the semiconductor device.

### CROSS REFERENCE TO RELATED APPLICATION

The present application claims priority to Korean Patent Application No. 10-2021-0169861, filed Dec. 1, 2021, the entire contents of which are incorporated herein for all purposes by this reference.

### BACKGROUND OF THE INVENTION

### Field of the Invention

The present disclosure relates to a high voltage semiconductor device and to a method of manufacturing the high voltage semiconductor device. More specifically, the present disclosure relates to a high voltage semiconductor device and to a method of manufacturing the high voltage semiconductor device, the high voltage semiconductor device being configured to exclude a conventional deep NDT region in a body region, but include a HV-NLDD region so that the width of the body region is minimized, thereby improving integration and on-resistance characteristics of the semiconductor device.

### Description of the Related Art

A Laterally Diffused Metal Oxide Semiconductor (LDMOS) is a representative power device having a rapid switching response and a high input impedance. Hereinafter, a structure and a manufacturing process of a conventional LDMOS device will be described in detail.

FIG. 1 is a cross-sectional view illustrating a conventional high voltage semiconductor device.

First, in a conventional LDMOS device 9, when a body region 910 is formed, a first low-concentration NDT region 911 having a first conductivity type is first formed, and then a second high-concentration SDNW region 913 having the first conductivity type is formed. That is, the first region 911 having the low concentration is formed relatively deeply in order to improve the breakdown voltage, and then the second region 913 having the high concentration is formed, thereby forming the body region 910 having a high dopant concentration.

The first region 911 overlaps a gate electrode 930 that is adjacent to the first region 911. Generally, the first region 911 has a width sufficient to prevent a situation in which the gate electrode 930 does not overlap with the first region 911 in the event that an alignment error occurs when the gate electrode 930 is formed.

In other words, when the gate electrode 930 is formed, even if the gate electrode 930 is misaligned (rather than in an expected position), the first region 911 is sufficiently wide to provide a margin that maintains an overlapping state of the gate electrode 930 with the first region 911. As a result, the size of the device 9 is relatively large, and the on-resistance may decrease. Therefore, the competitiveness of the device 9 may be relatively low.

In order to solve these problems, the present inventor conceived a high voltage semiconductor device having a new structure and a method of manufacturing the high voltage semiconductor device. The detailed description thereof is provided below.

### Document of Related Art

Korean Patent Application Publication No. 10-2012-0055139, entitled “LDMOS SEMICONDUCTOR DEVICE.”

### SUMMARY OF THE INVENTION

Accordingly, the present disclosure has been made keeping in mind the above problems occurring in the related art.

An objective of the present disclosure is to provide a high voltage semiconductor device and a method of manufacturing the high voltage semiconductor device, the high voltage semiconductor device being configured to exclude a low-concentration first NDT region (which may have a second conductivity type) so a margin for ensuring overlap of the first NDT region and a gate electrode is not considered, thereby preventing the width of the body region from becoming larger than necessary.

In addition, as described above, another objective of the present disclosure is to provide a high voltage semiconductor device and a method of manufacturing the high voltage semiconductor device, the high voltage semiconductor device having a reduced or minimal body region width, thereby being capable of satisfying relatively advanced design rules, and improving device integration and on-resistance characteristics accordingly.

In addition, still another objective of the present disclosure is to provide a high voltage semiconductor device and a method of manufacturing the high voltage semiconductor device, the high voltage semiconductor device being configured such that a HV-NLDD region is formed using a gate spacer as a ion implantation mask, thereby omitting a separate or additional mask for forming the HV-NLDD region, and making the manufacturing process relatively convenient.

In addition, yet another objective of the present disclosure is to provide a high voltage semiconductor device and a method of manufacturing the high voltage semiconductor device, the high voltage semiconductor device and method being configured to perform a tilt implant process when forming the HV-NLDD region, thereby ensuring that the gate electrode sufficiently overlaps the HV-NLDD region.

The present disclosure may be implemented by one or more embodiments having some or all of the following configurations, to achieve one or more of the above-described objectives.

According to one or more embodiments of the present disclosure, there is provided a high voltage semiconductor device including a drift region on, in or above a substrate (e.g., in a first region); a body region on, in or above the substrate (e.g., in a second, different region); a drain in the drift region; a source in the body region; a body contact in the body region, the body contact being in contact with or adjacent to the source; a gate electrode on or above the substrate, the gate electrode being between the drain and the source; and a high-concentration LDD region in contact with the source, the LDD region overlapping the gate electrode.

In the high voltage semiconductor device of the present disclosure, the body region may have a substantially uniform concentration.

In the high voltage semiconductor device of the present disclosure, the LDD region may be more shallow (e.g., it has a smaller depth) than the source and the body contact.

The high voltage semiconductor device of the present disclosure may further include a gate insulation film between the gate electrode and a surface of the substrate; and gate spacers on sidewalls of the gate electrode. The LDD region may be formed, for example, by ion implantation, utilizing the gate spacers as a mask.

The high voltage semiconductor device of the present disclosure may further include a gate field plate between the gate electrode and the drain.

According to one or more other embodiments of the present disclosure, there is provided a high voltage semiconductor device including a drift region having a first conductivity type on or above a substrate; a body region having a second conductivity type on or above the substrate, the body region having a substantially uniform doping concentration; a drain extension region having the first conductivity type in the drift region; a drain having the first conductivity type in the drain extension region; a source having the second conductivity type in the body region; a body contact having the first conductivity type in the body region, the body contact being in contact with or adjacent to the source; a gate electrode in an active region, the gate electrode being between the drain and the source; gate spacers on sidewalls of the gate electrode; and an LDD region having the second conductivity type, the LDD region in contact with the source and overlapping the gate electrode. The LDD region may be formed by ion implantation within a space between nearest ones of the gate spacers on adjacent gate electrodes. The LDD region is may be configured to tolerate or withstand a high voltage (e.g., up to a maximum voltage of 30-50 V).

The high voltage semiconductor device of the present disclosure may further include a silicide film on the source, the body contact, the gate electrode, and/or the drain.

The high voltage semiconductor device of the present disclosure may further include a buried layer having the second conductivity type below the drift region; and a guard ring having the second conductivity type connected to the buried layer.

The guard ring may include a lower second conductivity type well, which may be configured to tolerate a high voltage (as described above); and an upper second conductivity type well connected to a high-concentration region having the second conductivity type and the lower second conductivity type well.

The LDD region may be formed by ion implantation, utilizing the gate spacers (e.g., as an implantation mask), without forming a photoresist pattern on or above the substrate prior to the ion implantation. The LDD region may also have a depth smaller than depths of the source region and the body contact.

According to one or more embodiments of the present disclosure, there is provided a method of manufacturing a high voltage semiconductor device, the method including forming a drift region on or in a substrate; forming a body region on or in the substrate, the body region being a predetermined distance from the drift region; depositing a gate film on or above the substrate after forming the body region; etching the gate film to form a gate electrode having sidewalls; forming a gate spacer on the sidewalls of the gate electrode; and forming an LDD region (e.g., a source/drain extension or tip) having a high concentration of a second conductivity type dopant after forming the gate spacer.

In the method of manufacturing the high voltage semiconductor device of the present disclosure, forming the LDD region having the second conductivity type may comprise ion implantation utilizing the gate spacer(s) as a mask, and the LDD region may overlap the gate electrode (or adjacent gate electrodes, when the method forms a plurality of gate electrodes).

In the method of manufacturing the high voltage semiconductor device of the present disclosure, forming the LDD region may comprise a tilt implant process.

The method of manufacturing the high voltage semiconductor device of the present disclosure may further include forming a dopant region having the second conductivity type in the body region after forming the LDD region, the dopant region overlapping the LDD region; and separately forming a source and a body contact by separately implanting dopants having a first conductivity type, overlapping the dopant region in the body region.

The method of manufacturing the high voltage semiconductor device of the present disclosure may further include forming a drain in or on the substrate, and forming a silicide film on each of the source, the gate electrode, and the drain.

According to one or more other embodiments of the present disclosure, there is provided a method of manufacturing a high voltage semiconductor device, the method including forming a buried layer in a substrate; forming a drift region in or on a surface of the substrate utilizing a first photoresist pattern as a first mask; forming a body region on or in the surface of the substrate, utilizing a second photoresist pattern as a mask, the body region being a predetermined distance from the drift region; depositing a gate film on or over the substrate after forming the body region; etching the gate film to form a gate electrode having sidewalls; forming a gate spacer on the sidewalls of the gate electrode; and forming an LDD region having a high concentration of a second conductivity type dopant by ion implantation, using the gate spacer as a third mask. The LDD region may be configured to tolerate or withstand a high voltage.

The method of manufacturing the high voltage semiconductor device of the present disclosure may further include forming a guard ring by implanting a dopant having the second conductivity type, utilizing a third photoresist pattern as a fourth mask.

The method of manufacturing the high voltage semiconductor device of the present disclosure may further include forming a drain extension region in the drift region utilizing a fourth photoresist pattern as a fifth mask; forming a drain in the drain extension region utilizing a fifth photoresist pattern as a sixth mask; and forming a source in the body region.

According to the above configurations, the present disclosure has the following effects.

In the present disclosure, the present high voltage semiconductor device omits the low-concentration NDT region having the second conductivity type, so a margin for ensuring the overlap of the first region and the gate electrode is not considered, thereby preventing the width of the body region from becoming larger than necessary.

In addition, in the present disclosure, as described above, since the width of the body region is minimized, relatively small design rules may be satisfied, the device may be more highly integrated, and the on-resistance characteristics may be increased.

In addition, in the present disclosure, since the HV-NLDD region is formed utilizing the gate spacer as an ion implantation mask, a separate and/or additional mask formation process for forming the HV-NLDD region may be omitted, making the manufacturing process relatively convenient.

In addition, in the present disclosure, since a tilt implant process is used to form the HV-NLDD region, the gate electrode may sufficiently overlap the HV-NLDD region.

Meanwhile, though not explicitly mentioned, effects described in the present specification and tentative effects expected from the technical features of the present specification will be treated as being described in the present specification.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a conventional high voltage semiconductor device;

FIG. 2 is a cross-sectional view illustrating a high voltage semiconductor device according to one or more embodiments of the present disclosure;

FIG. 3 is a graph illustrating improved on-resistance characteristics of the high voltage semiconductor device according to FIG. 2; and

FIGS. 4 to 13 are reference cross-sectional views illustrating a method of manufacturing a high voltage semiconductor device according to one or more embodiments of the present disclosure.

### DETAILED DESCRIPTION OF THE INVENTION

Hereinafter, embodiments of the present disclosure will be described in detail with reference to accompanying drawings. Various changes to the following embodiments are possible, and the scope of the present disclosure is not limited to the following embodiments. The patent right(s) associated with the present disclosure should be defined by the scope and spirit of the accompanying claims. In addition, embodiments of the present disclosure are intended to fully describe the present disclosure to a person having ordinary knowledge in the art to which the present disclosure pertains.

Hereinafter, when it is described that a component (or a layer) is referred to as being “on” another component (or another layer), it should be understood that the component may be directly on the other component, or one or more intervening components (or layers) may also be present. In contrast, when it is described that a component is referred to as being directly on another component, it should be understood that there is (are) no intervening component(s) present. In addition, terms such as “on”, “above”, “below”, “on an upper side of”, “on a lower side of”, “on a first side of”, and “on a side surface of” are intended to mean a relative position of the components.

The terms “first”, “second”, “third”, etc. may be used to describe various items, such as various elements, regions, and/or parts, but the items are not limited by the terms.

In addition, when a specific embodiment may be implemented differently, a specific process order may be performed differently from the described order. For example, two consecutively described processes may be performed substantially at the same time or performed in an order opposite to the described order.

The term “Metal-Oxide Semiconductor” (MOS) as used herein is a general term, and the metal “M” is not limited only to metal, but may be any conductive material. In addition, the semiconductor “S” may be a substrate or a semiconductor structure, and the oxide “O” is not limited only to an oxide, but may include any of various types of organic materials or inorganic insulating materials.

In addition, conductivity types or doped areas of elements may be defined as “p-type” or “n-type” according to main carrier characteristics, but this is only for convenience of description, and the technical idea of the present disclosure is not limited thereto. For example, hereinafter, the “p-type” or “n-type” may be referred to as the more general terms a “first conductivity type” or “second conductivity type”. Herein, the first conductivity type may refer to p-type conductivity, and the second conductivity type may refer to n-type conductivity.

In addition, it is to be understood that the terms “high-concentration” and “low-concentration” in reference to the doping or dopant concentration in an impurity region refer to relative doping or dopant concentrations of one impurity region relative to another impurity region.

Hereinafter, a high voltage semiconductor device may be a LDMOS device as an example.

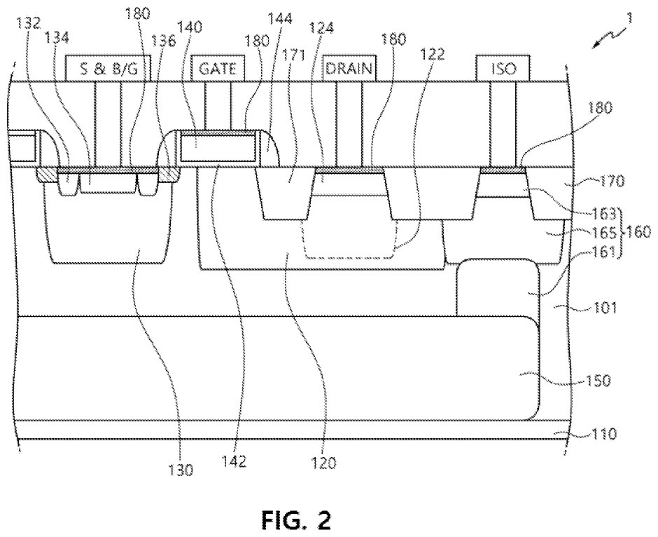

FIG. 2 is a cross-sectional view illustrating a high voltage semiconductor device according to one or more embodiments of the present disclosure.

Hereinafter, the high voltage semiconductor device according to an embodiment of the present disclosure will be described in detail with reference to the accompanying drawings.

Referring to FIG. 2, the present disclosure relates to a high voltage semiconductor device 1. More specifically, the present disclosure relates to the high voltage semiconductor device 1, the high voltage semiconductor device 1 not including a conventional deep NDT region in the body region 130, but including a HV-NLDD region 136 and a body region 130 with a minimal width, thereby improving integration of the semiconductor device 1 and its on-resistance characteristics.

First, the high voltage semiconductor device 1 according to one or more embodiments of the present disclosure includes a substrate 110. A semiconductor layer (e.g., a layer of epitaxial silicon or silicon-germanium) 101 may be on the substrate 110. A well region (not identified) utilized as or otherwise forming an active region may be in the semiconductor layer 10, and such an active region may be defined by a device isolation film 170. The substrate 110 may comprise a single crystal semiconductor substrate doped with a first conductive type dopant, or a p-type diffusion region in such a substrate, or a p-type epitaxial layer 101 on a single-crystal semiconductor 110. The device isolation film 170 may be formed by shallow trench isolation (STI), and there is no specific limitation.

In addition, the high voltage semiconductor device 1 preferably comprises a gate field plate 171 between a gate electrode 140 and a drain 124 that will be described later, thereby preventing an electric field from concentrating at an edge of the gate electrode 140. The gate field plate 171 may be formed by local oxidation of silicon (LOCOS).

A drift region 120 having a first conductivity type may be in or at a surface of the substrate 110. The drift region 120 is spaced predetermined distance apart from a body region 130 that will be described later. When a dopant concentration of the drift region 120 is equal to or less than a predetermined level, the on-resistance Rsp deteriorates, whereas when the dopant concentration is greater than the predetermined level, the on-resistance Rsp improves, but the breakdown voltage deteriorates. Therefore, it is preferable that the drift region have a dopant concentration appropriate for and/or considering the corresponding characteristics (i.e., the on-resistance and the breakdown voltage). It is more preferable that the drift region 120 have a dopant concentration that is lower than a dopant concentration of the drain 124 that will be described later.

A drain extension region 122 may be in the drift region 120, and such a drain extension region 122 is spaced a predetermined distance apart from the body region 130 that will be described later. In addition, it is preferable that the drain extension region 122 has the first conductivity type and has a dopant concentration higher than the dopant concentration of the drift region 120. The drain extension region 122 may increase the breakdown voltage of the high voltage semiconductor device 1. In addition, the drain 124 is in or on the drain extension region 122. The drain 124 may be electrically connected to a drain electrode (not numbered). Furthermore, it is preferable that such a drain 124 has the first conductivity type and has a dopant concentration higher than the dopant concentration of the drain extension region 122.

The body region 130 having a second conductivity type is on or in the surface of the substrate 110. Such a body region 130 is spaced a predetermined distance apart from the drift region 120.

Hereinafter, problems of a conventional high voltage semiconductor device 9 and a structure of the present disclosure for solving the problems will be described in detail.

First, in a conventional LDMOS device 9, when a body region 910 is formed, a first low-concentration NDT region 911 having the first conductivity type is formed first, and then a second high-concentration SDNW region 913 having the first conductivity type is formed. That is, the first region 911 having the low concentration is formed relatively deeply in order to improve a breakdown voltage, and then the second region 913 having the high concentration is formed, thereby forming the body region 910 having a high dopant concentration.

The first region 911 overlaps the gate electrode 930 that is adjacent to the first region 911. Generally, the first region 911 has a width sufficient to prevent insufficient overlap with the gate electrode 930 in the event that an alignment error occurs when the gate electrode 930 is formed.

In other words, when the gate electrode 930 is formed, even if the gate electrode 930 is misaligned (rather than in an expected position), the first region 911 is sufficiently wide to provide a margin that maintains an overlapping state of the gate electrode 930 with the first region 911. As a result, the size of the device 9 is relatively large, and the on-resistance may decrease. Therefore, the competitiveness of the device 9 may be relatively low.

In order to prevent and/or solve such problems, in the body region 130 of the high voltage semiconductor device 1 according to one or more embodiments of the present disclosure, the conventional first region 911 is not present, but a high-concentration well region having the second conductivity type corresponding to the second region 913 is. In addition, a source 132 having the second conductivity type is at or in a surface of the substrate 110 in the body region 130. The source 132 may be electrically connected to a source electrode S & B/G. In addition, a body contact 134 having the first conductivity type may be adjacent to the source 132. In addition, the body contact 134 and the source 132 may be in contact with each other.

In addition, while a first side of a high voltage Lightly Doped Drain (LDD) region 136 having the second conductivity type is facing a first side of the body contact 134, a second side of the high voltage LDD region 136 extends such that the second side of the high voltage LDD region 136 overlaps a bottom side of the gate electrode 140 that is adjacent to the high voltage LDD region 136. In more detail, while the first side of the LDD region 136 is in contact with the body contact 134, the second side of the LDD region 136 may extend beyond the body region 130 to a position overlapping the gate electrode 140. Preferably, a dopant concentration of the LDD region 136 is higher than the dopant concentration of the body region 130. Without utilizing a separate ion implantation mask during a process of forming such an LDD region 136, the LDD region 136 is capable of being formed by performing a tilt implant. In addition, it is preferable that the LDD region 136 is more shallow than the source 132 and the body contact 134.

That is, conventionally, due to the manufacturing process, the first region 911 and the second region 913 are formed before the gate electrode 930 is formed. To ensure the overlap of the gate electrode 930 with the first region 911, the implant mask for the first region 911 is made with sufficient margin (e.g., along the width of the first region 911; i.e., the width of the opening in the implant mask is greater than the space between adjacent gate electrodes 930).

On the other hand, the LDD region 136 according to one or more embodiments of the present disclosure is formed after the gate electrode 140 is formed. Furthermore, by utilizing adjacent gate spacers 144 that are between adjacent gate electrodes 140 and spaced apart from each other, a separate implant mask for the LDD region 136 may not be necessary. By forming the LDD region 136 by tilt implantation, overlap of the LDD region 136 with the gate electrode 140 is ensured. Therefore, compared to the conventional high voltage semiconductor device manufacturing process, at least one process step is omitted in the present process, which may increase productivity.

The gate electrode 140 is on the surface of the substrate 110. Specifically, in the active region, the gate electrode 140 may be between the drain 124 and the source 132. Such a gate electrode 140 is on or over a channel region, and the channel region is capable of being turned on or turned off by a voltage applied to the gate electrode 140. For example, the gate electrode 140 may comprise a conductive polysilicon, a metal, a conductive metal nitride, or a combination thereof, and may be formed by a process such as chemical vapor deposition (CVD), physical vapor deposition (PVD; e.g., sputtering, evaporation, etc.), atomic layer deposition (ALD), metal-organic atomic layer deposition (MOALD), a metal-organic chemical vapor deposition (MOCVD), or the like. In addition, a gate insulation film 142 is between the gate electrode 140 and the surface of the substrate 110. A sidewall insulation film (not numbered) may be on a side surface of the gate electrode 140, between the gate electrode 140 and the spacer 144. The gate insulation film 142 and the sidewall insulation film may comprise a silicon oxide film (e.g., undoped silicon dioxide), a high-k dielectric film, or a combination thereof. In addition, the gate insulation film 142 may be formed by atomic layer deposition (ALD), chemical vapor deposition (CVD), physical vapor deposition (PVD), thermal growth or oxidation, or the like.

In addition, side surfaces of the gate electrode 140 and the gate insulation film 142 (or, alternatively, the unnumbered insulation film) may contact a gate spacer 144. The gate spacer 144 may comprise an oxide film (e.g., silicon dioxide), a nitride film (e.g., silicon nitride), or a combination thereof. As described above, due to the gate spacer 144, the LDD region 136 can be without a separate ion implantation mask (except perhaps to block the exposed areas of the substrate/semiconductor layer 101 other than the body region 130, for example corresponding to the drain extension 122 and/or drain 124, the guard ring 160, etc.).

In addition, a buried layer 150 having the second conductivity type may be below the drift region 120. The buried layer 150 may be above the substrate 110, in the semiconductor layer 101, and is configured to restrain electrons from entering or passing through to the substrate 110 in response to a voltage applied to the drain 124 (e.g., via a drain electrode DRAIN). That is, a punch-through current (e.g., comprising such electrons) may be restrained by the buried layer 150.

A guard ring 160 connected to the buried layer 150 may be between the drain 124 and a peripheral device isolation film 170. The guard ring 160 may comprise a lower second conductivity type well 161 (which may be configured to tolerate or withstand a high voltage as described herein), an upper second conductivity type well 165 connected to the lower second conductivity type well 161, and a high-concentration region 163 having the second conductivity type and connected to the upper second conductivity type well 165. The guard ring 160 may reduce leakage current and increase a safe operating area (SOA) of the device 1.

In addition, a silicide film 180 comprising a metal may be on each of uppermost surfaces of the drain 124, the source 132, the gate electrode 140, and the body contact 134. Generally, in order to improve contact resistance and thermal stability of a MOSFET device, the silicide film 180 is formed by a self-aligned silicide process using a refractory metal such as cobalt (Co), nickel (Ni), titanium (Ti), tungsten (W), or the like.

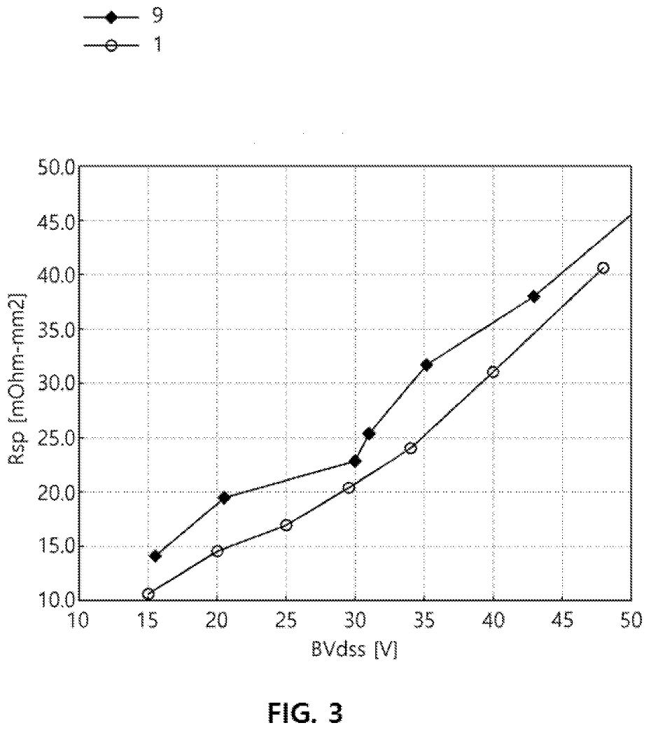

FIG. 3 is a graph illustrating improved on-resistance of the high voltage semiconductor device according to FIG. 2.

Referring to FIG. 3, by the structure of the high voltage semiconductor device 1 according to the present disclosure, the on-resistance (Rsp; the resistance of the device 1 when a current first flows in the channel and/or when the device 1 is first turned on) is reduced. An Rsp value of the present device 1 is lowered by an average of approximately 27% compared to an Rsp value of the conventional device 9. This is an advantage that naturally occurs since the area of the device 1 is reduced relative to the device 9.

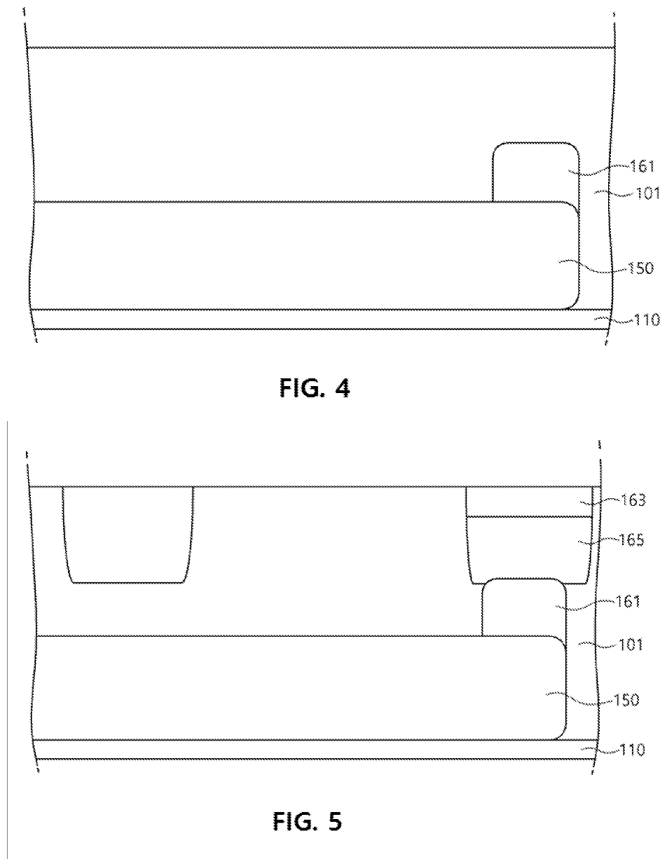

FIGS. 4 to 13 are reference cross-sectional views illustrating a method of manufacturing a high voltage semiconductor device according to one or more embodiments of the present disclosure.

Hereinafter, a method of manufacturing the high voltage semiconductor device according to one or more embodiments of the present disclosure will be described in detail with reference to the accompanying drawings. It should be noted that the order of steps in the process of forming each configuration in the drawings may be different from the order described herein, or the steps may be performed at substantially the same time. In addition, the method of manufacturing the configurations in the drawings described herein is only for illustrative purposes, and the scope of the present disclosure is not limited thereto.

First, referring to FIG. 4, an epitaxial layer 101 having the first conductivity type is formed on the substrate 110 (e.g., by epitaxial growth, using a material that forms a crystalline structure substantially identical to the crystal structure of the substrate 110, and a relatively low dose of a first conductivity type dopant). The epitaxial layer 101 may comprise a lower epitaxial layer and a sequentially formed, substantially identical upper epitaxial layer. In addition, for example, the buried layer 150 having the second conductivity type is formed in the epitaxial layer 101 by ion implantation (e.g., a buried ion implantation process).

Then, in order to form the guard ring 160, a photoresist pattern (not illustrated) is formed (e.g., on the lower epitaxial layer), and then the lower second conductivity type well 161 is formed by injecting a second conductivity type dopant into the lower epitaxial layer using the photoresist pattern as a mask. Such a lower second conductivity type well 161 is connected to a first region or location of the buried layer 150. Then, the photoresist pattern may be removed by conventional ashing and/or stripping.

Referring to FIG. 5, the body region 130 having the second conductivity type, the high-concentration region 163 having the second conductivity type, and the upper second conductivity type well 165 are formed by ion implantation into the upper epitaxial layer using a photoresist pattern as a mask. The body region 130 and the upper well 165 may be formed at the same time (i.e., in the same processing steps).

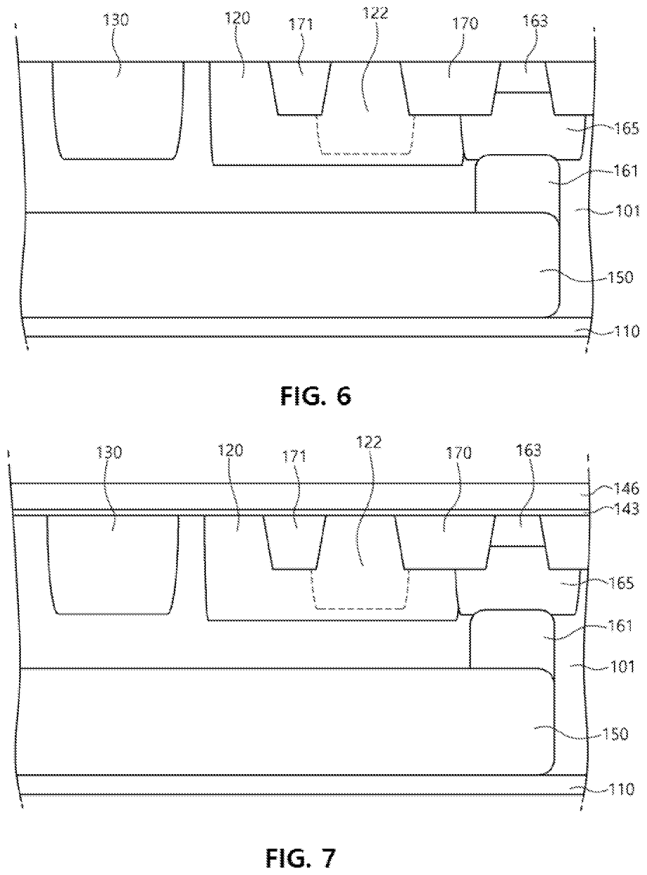

Next, referring to FIG. 6, photoresist patterns (not illustrated) are formed that separately and/or respectively expose the locations of the drift region 120 and the drain extension region 122, then the drift region 120 and the drain extension region 122 are separately formed by injecting one or more dopants having the first conductivity type into the exposed locations of the upper epitaxial layer. After each injection of first conductivity type dopant ions, the photoresist pattern is removed by conventional ashing and/or stripping.

The active region may then be defined by forming the device isolation film 170. As described above, the device isolation film 170 may be formed by shallow trench isolation (STI). The gate field plate 171 may also be formed at this time. The gate field plate 171 may be formed by local oxidation of silicon (LOCOS) or STI. If formed by STI, the device isolation film 170 and the gate field plate 171 may be formed at the same time (i.e., in the same processing steps).

Referring to FIG. 7, the gate insulation film 143 is formed in or on the active region, on or at the surface of the epitaxial layer 101, by thermal oxidation (in which case it is not formed on or over the device isolation film 170 and the gate field plate 171), or blanket deposition (e.g., CVD, PVD, ALD, etc.). Furthermore, as an example, in order to form the gate electrode 140 on the insulation film 143, a gate film 146 comprising a conductive polysilicon film is blanket-deposited on the gate insulation film 143. However, it should be noted that the gate film 146 may comprise a conductive polysilicon film, a conductive metal nitride, a conductive metal silicide, or a combination thereof. In addition, the gate insulation film 143 may comprise the silicon oxide film, the high-k dielectric film, or a combination thereof, as described herein.

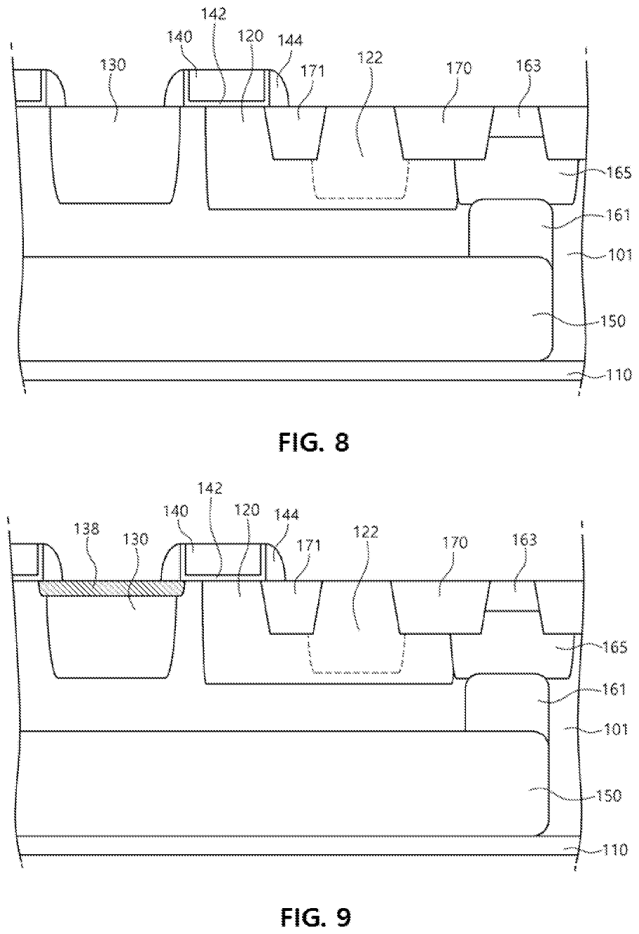

Then, referring to FIG. 8, after forming a photoresist pattern (not illustrated) on the gate film 146 to form the gate electrode 140, the gate film 146 and the insulation film 143 are sequentially etched. Accordingly, the gate electrodes 140 and the gate insulation films 142 are formed.

Thereafter, for example, one or more insulation films (not shown) are deposited onto the gate electrode 140 and the exposed structures on/in the epitaxial layer 101 by CVD, and the gate spacers 144 are formed on sidewalls of the gate electrode 140 by anisotropic dry etching.

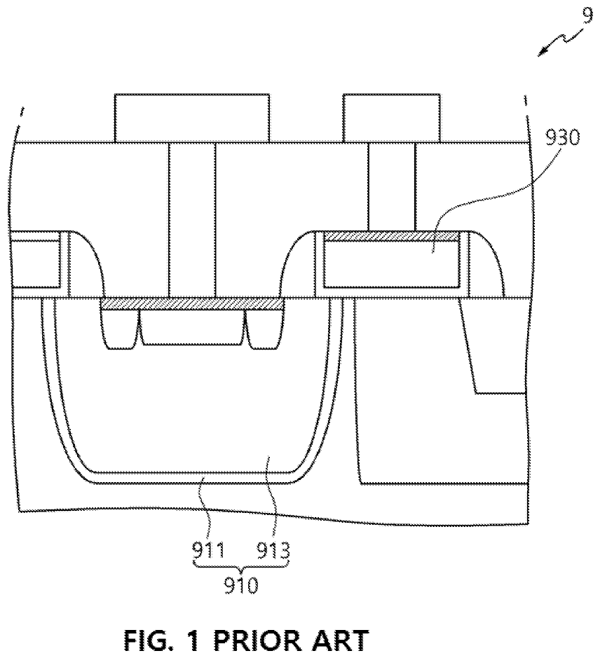

Referring to FIG. 9, after the gate electrode 140 is formed, a high-concentration region 138 having the second conductivity type for forming the LDD region 136 is formed. Specifically, the high-concentration region 138 having the second conductivity type 138 may be formed by ion implantation using the gate spacer 144 as a mask. Optionally, a conventional photoresist pattern may mask or cover the guard ring 160, the drain extension region 122 and/or the drift region 120, the device isolation film 170, the gate field plate 171, and optionally, part or all of the gate electrodes 140. As described above, for example, the LDD region 136 may be formed by tilt implantation, so that a separate margin for ensuring overlap of the gate electrode 140 with the body region 130 (or the conventional NDT region 911; FIG. 1) is not necessary. That is, when forming the conventional NDT region 911, the concentration, the depth, and the width of the NDT region 911 are controlled during the ion implantation process, and it may be difficult to satisfy minimum design rules with a minimum margin. In order to solve these problems, the first region 911 is omitted, and the LDD region 136 is formed.

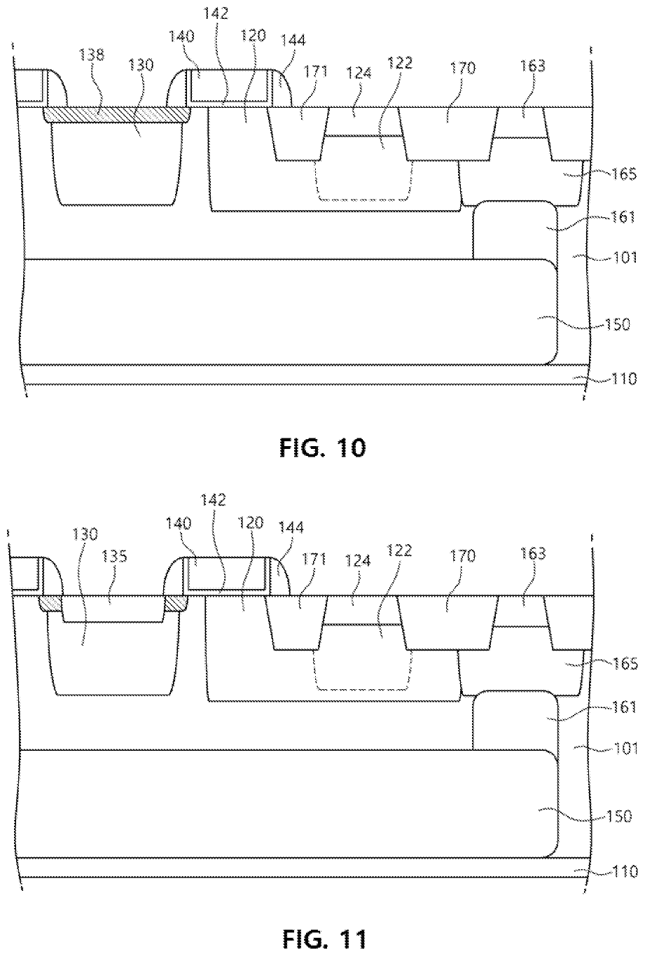

Then, referring to FIG. 10, the drain 124 having a high concentration of a first conductivity type dopant is formed by ion implantation between the device insulation film 170 and the gate field plate 171. This ion implantation may be performed using a photoresist pattern as a mask.

Then, referring to FIG. 11, a dopant region 135 having the second conductivity type is formed in the body region 130 by ion implantation. This ion implantation may be performed using a photoresist pattern as a mask. The dopant region 135 is formed in the space between adjacent gate spacers 144, and overlaps the high-concentration region 138 having the second conductivity type. Accordingly, the LDD region 136 may be formed as illustrated in the drawings.

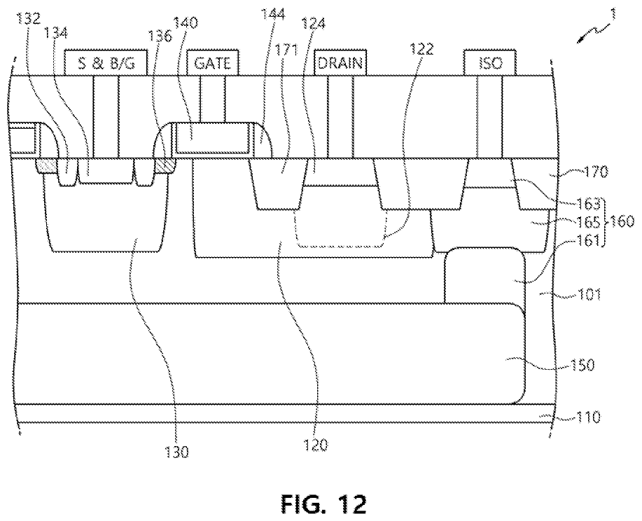

Then, referring to FIG. 12, the body contact 134 is formed by ion implantation into the high-concentration region 138 using a photoresist pattern as a mask. Parts of the high-concentration region 138 adjacent to the gate spacers 144 are covered by the photoresist pattern, thereby forming the source(s) 132. Accordingly, the source 132 and the body contact 134 may be formed as illustrated in the drawings.

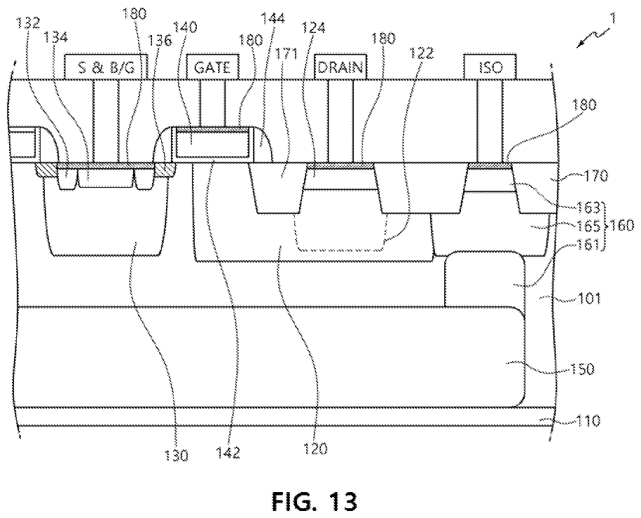

Finally, referring to FIG. 13, prior to forming a pre-metal insulation layer (not numbered), contacts (not numbered) in the pre-metal insulation layer, and metal electrodes S & B/G, GATE, DRAIN and ISO, a self-aligned silicide process (e.g., salicide process) may be performed to form a silicide film 180 on the drain 124, the source 132, the body contact 134, and the upper surface of the substrate 110 by blanket-depositing a refractory metal film comprising cobalt (Co), nickel (Ni), titanium (Ti), tungsten (W) or the like, annealing to form the corresponding metal silicide, and selectively removing the unreacted refractory metal to improve contact resistance and thermal stability.

The foregoing detailed description is for illustrative purpose only. In addition, the description provides embodiments of the present disclosure, and the present disclosure may be used in other various combination, changes, and environments. That is, the present disclosure may be changed or modified within the scope of the present disclosure described herein, a range equivalent to the description, and/or within the knowledge or technology in the related art. The embodiments show optimum states for achieving the spirit of the present disclosure and may be changed in various ways for the detailed application fields and use of the present disclosure. Therefore, the detailed description of the present disclosure is not intended to limit the present disclosure.

What is claimed is:

1. A high voltage semiconductor device comprising:
a drift region on, in or above a substrate;
a body region on, in or above the substrate;
a drain in the drift region;
a source in the body region;
a body contact in the body region, the body contact being in contact with or adjacent to the source;
a gate electrode on or above the substrate, the gate electrode being between the drain and the source; and
a high-concentration LDD region, the LDD region being in contact with the source, and the LDD region overlaps the gate electrode.

2. The high voltage semiconductor device of claim 1, wherein the body region has a substantially uniform concentration.

3. The high voltage semiconductor device of claim 2, wherein the LDD region is more shallow than the source and the body contact.

4. The high voltage semiconductor device of claim 2, further comprising:
a gate insulation film between the gate electrode and the substrate; and
gate spacers on sidewalls of the gate electrode.

5. The high voltage semiconductor device of claim 4, further comprising a gate field plate between the gate electrode and the drain.

6. A high voltage semiconductor device comprising:
a drift region having a first conductivity type above a substrate;
a body region having a second conductivity type above a second side of the substrate, the body region having a substantially uniform doping concentration;
a drain extension region having the first conductivity type in the drift region;
a drain having the first conductivity type in the drain extension region;
a source having the second conductivity type in the body region;
a body contact having the first conductivity type in the body region, the body contact being in contact with or adjacent to the source;
a gate electrode above the substrate, the gate electrode being between the drain and the source;
gate spacers on sidewalls of the gate electrode; and
an LDD region having the second conductivity type, the LDD region having a high voltage and that is in contact with the source, and the LDD region overlaps the gate electrode, wherein the LDD region is formed by ion implantation in a space between nearest ones of the gate spacers on adjacent gate electrodes.

7. The high voltage semiconductor of claim 6, further comprising a silicide film on the source, the body contact, the gate electrode, and/or the drain.

8. The high voltage semiconductor device of claim 6, further comprising:
a buried layer having the second conductivity type below the drift region; and
a guard ring having the second conductivity type connected to the buried layer.

9. The high voltage semiconductor device of claim 8, wherein the guard ring comprises:
a lower second conductivity type well; and
an upper second conductivity type well connected to a high-concentration region having the second conductivity type and the lower second conductivity type well.

10. The high voltage semiconductor device of claim 6, wherein the LDD region has a depth smaller than depths of the source region and the body contact.

11. A method of manufacturing a high voltage semiconductor device, the method comprising:
forming a drift region on or in a substrate;
forming a body region on or in the substrate, the body region being a predetermined distance from the drift region;
depositing a gate film on or above the substrate after forming the body region;
etching the gate film to form a gate electrode having sidewalls;
forming a gate spacer on the sidewalls of the gate electrode; and
forming a high-concentration LDD region having a second conductivity type, after forming the gate spacer.

12. The method of claim 11, wherein forming the LDD region having the second conductivity type comprises ion implantation utilizing the gate spacers as a mask, and the LDD region having the second conductivity type overlap adjacent gate electrodes.

13. The method of claim 12, wherein forming the LDD region having the second conductivity type comprises a tilt implant process.

14. The method of claim 12, further comprising:
forming a dopant region having the second conductivity type in the body region after forming the high-concentration region having the second conductivity type, the dopant region overlapping the LDD region; and
separately forming a source and a body contact by separately implanting dopants having a first conductivity type, overlapping the dopant region having the second conductivity type in the body region.

15. The method of claim 12, further comprising forming a drain in or on the substrate, and forming a silicide film on each of the source, the gate electrode, and the drain.

16. A method of manufacturing a high voltage semiconductor device, the method comprising:
forming a buried layer in a substrate;
forming a drift region on or in the substrate utilizing a first photoresist pattern as a first mask;
forming a body region on or in the substrate utilizing a second photoresist pattern as a second mask, the body region being a predetermined distance from the drift region;
depositing a gate film on or over the substrate after forming the body region;
etching the gate film to form a gate electrode having sidewalls;
forming a gate spacer on the sidewalls of the gate electrode; and
after forming the gate spacer, forming a high-concentration region having a second conductivity type by ion implantation utilizing the gate spacer as a third mask.

17. The method of claim 16, further comprising forming a guard ring by implanting a dopant having the second conductivity type, utilizing a third photoresist pattern as a fourth mask.

18. The method of claim 17, further comprising:
forming a drain extension region in the drift region utilizing a fourth photoresist pattern as a fifth mask;
forming a drain in the drain extension region utilizing a fifth photoresist pattern as a sixth mask; and
forming a source in the body region.
